(19) United States
(12) Patent Application Publication
(10) Pub. No.: US 2007/0128739 A1
(43) Pub. Date: Jun. 7, 2007

(54) METHOD FOR MAKING TOOLS FOR MICRO REPLICATION

(76) Inventors: Randall H. Wilson, Albuquerque, NM (US); Junwon Lee, Webster, NY (US); John P. Hannigan, Spencerport, NY (US); Robert P. Bourdelais, Pittsford, NY (US); Stephen C. Meissner, West Henrietta, NY (US)

Correspondence Address: Andrew J. Anderson;Patent Legal Staff, Eastman Kodak Company, 343 State Street, Rochester, NY, 14650-2201, US

(21) Appl. No.: 11/567,770

(22) Filed: Dec. 7, 2006

Related U.S. Application Data
(63) Continuation-in-part of application No. 10/859,652, filed on Jun. 3, 2004.

(51) Int. Cl. H01L 21/66; H01L 23/58

(52) U.S. Cl. 438/14; 257/48

(57) ABSTRACT

A method includes electro-mechanical engraving a pattern of cavities with well defined shapes in a surface. The surface is configured to micro replicate according to the pattern. The surface may be a pattern roller. The cavities may have complex cross sections and may be cut by multiple cutters. The molding pattern may be for micro replication of optical elements of a light redirecting film or a light extracting film.

### CROSS REFERENCE TO RELATED APPLICATION

This application is a Continuation-in-Part of U.S. Ser. No. 10/859,652 filed Jun. 3, 2004, the contents of which are incorporated herein by reference.

### FIELD OF THE INVENTION

Example embodiments of the present invention relate to a method of electro-mechanical engraving a molding pattern consisting of small, individual cavities, in a rigid surface for the specific purpose of micro replicating the inverse of said three-dimensional pattern into a continuous web of material.

### BACKGROUND OF THE INVENTION

A light redirecting film may be used in a variety of applications. For example, a light redirecting film may be used as part of a liquid crystal display (LCD) to increase the power efficiency of the LCD. Increasing the power efficiency of a LCD (or other similar display) may be significant. Liquid crystal displays are often included in mobile devices (e.g. cellular telephones, laptop computers, digital cameras, etc.) which run on batteries. It is desirable for these mobile devices to maximize the operating time of their batteries. Although battery technology is improving, one way to increase the battery life of a mobile device is to reduce power consumption of the device without degrading quality. By making liquid crystal displays more efficient, the battery life of a mobile device can be extended, which is of great benefit to the user.

The optics of light redirecting films are very specific and detailed. Most light redirecting films comprise elongated prisms, in some cases with varying height or horizontal position along the length of the prisms. For example, PCT Published Application WO 00/48037 teaches the use of a diamond turning machine with a fast tool servo cutting head to produce rollers with a molding pattern to micro replicate a light redirecting film with elongated prisms that vary in height or horizontal position along their length.

For some applications, discrete optical elements have considerable advantages. Discrete optical elements are short in both length and width compared to the dimensions of the optical substrate on which they lie. Discrete optical elements may have advantages such as reducing wet-out of films, obscuring cosmetic defects, and reducing Moiré effects when the film is assembled into an LCD. As taught in U.S. patent application Ser. No. 11/388,582, incorporated herein by reference, discrete optical elements also have the distinct advantage of being able to vary in shape, position, density, pitch, length, and other attributes in a two-dimensional pattern on a light extracting film.

There is a need for methods to fabricate molds with large numbers of discrete cavities with well-defined and varying shapes and distributions in a short amount of time.

### SUMMARY OF THE INVENTION

Example embodiments of the present invention relate to a method including electro-mechanical engraving of a molding pattern in a rigid surface (e.g. a pattern roller). In some embodiments the cavities engraved in the molding pattern have complex cross sections. Other example embodiments of the present invention relate to a method including micro replicating optical elements on a light extracting film. Other embodiments of the present invention relate to an apparatus including a rigid surface. A molding pattern is formed in the rigid surface by electro-mechanical engraving (e.g. Gravure electro-mechanical engraving). In some embodiments the molding pattern is formed using multiple diamond cutters, where the relative positions of the cavities formed by the multiple cutters are accurately positioned to within very close tolerances.

A molding pattern is a three-dimensional surface shape formed on a rigid surface, such that the negative of the three-dimensional surface shape is accurately imparted to the surface of an object molded from the rigid surface. The molding pattern in the present invention comprises many well-formed cavities cut in the rigid surface, and the shape of the cavities is substantially the negative of the shape of the protrusions on an object molded from the rigid surface.

In accordance with example embodiments of the present invention, the manufacturing process is able to produce a molding pattern for optical films that can be used in a variety of applications. For example, by using the manufacturing process in accordance with example embodiments of the invention, a mold may be produced having discrete cavities with complex cross sections. A single mold may contain cavities with multiple cross sectional shapes. The cavities of multiple shapes may be interspersed with each other, and may be located relative to each other with high precision. The cavities may be cut at high speeds, allowing fabrication of a complete mold with many cavities within a reasonable amount of time. An optical film produced from the molding pattern comprises discrete optical elements and may have advantages in display quality, manufacturing cost, and optical efficiency.

### BRIEF DESCRIPTION OF THE DRAWINGS

FIG. 1 is a schematic side elevation view of a light redirecting film system, in accordance with example embodiments of the present invention.

FIG. 2 is an enlarged fragmentary side elevation view of a portion of a backlight and a light redirecting film system, in accordance with example embodiments of the present invention.

FIGS. 3 and 4 are schematic side elevation views of light redirecting film systems, in accordance with example embodiments of the present invention.

FIG. 5 shows a typical image cut by an electromechanical engraving machine, with cavities placed in a regular offset grid.

FIG. 6 shows another portion of a typical image cut by an electromechanical engraving machine, with cavities cut at various depths, size and shape.

FIG. 7 shows an illustration of an irregular or random pattern of intersecting cavities.

FIGS. 8A-C show illustrations of various types of neighboring, overlapping cavities.

FIG. 9 shows a lengthwise cross-section of an individual cavity and how it was cut to the desired finished depth in multiple steps.

FIG. 10 shows cylinder configurations that contain small cavities, in accordance with example embodiments of the present invention.

FIG. 11 shows a cross section of a light extracting feature, in accordance with example embodiments of the present invention.

FIG. 12 shows a complex cross section of a light turning feature, in accordance with example embodiments of the present invention.

FIG. 13 shows a cross section of a cavity for molding a light extracting feature, in accordance with example embodiments of the present invention.

FIG. 14 shows a cross section of a light extracting film with light extracting features having two distinct cross sections, in accordance with example embodiments of the present invention.

FIG. 15 shows front views of two diamond cutters, in accordance with example embodiments of the present invention.

FIGS. 16A and 16B show top views of patterns of interspersed cavities, in accordance with example embodiments of the present invention.

FIG. 17A shows a complex cross section of a feature on an optical film substrate, in accordance with example embodiments of the present invention.

FIG. 17B shows a cross section of a cavity and a diamond cutter, in accordance with example embodiments of the present invention.

FIG. 18 shows a cross section of a cavity and a diamond cutter with a flat tip, in accordance with example embodiments of the present invention.

### DETAILED DESCRIPTION OF THE INVENTION

There are numerous uses for cylinders with patterns of small cavities on their surfaces. Typically they are used to replicate the pattern of cavities in the cylinder surface into or onto another material in a continuous manufacturing process. For example, in Gravure printing, a series of cavities formed in a desired pattern on a cylinder surface are used to collect and then transfer ink or a coating material onto the surface of a continuous web.

Pattern cylinders may also be used in micro replication processes. In Ultraviolet (UV) curing replication, a material is applied to the cylindrical surface in a way to fill the cavities, the UV cured material cured by UV exposure and then separated from the cylinder. Other examples of micro replication processes include hot embossing and extrusion roll molding. In hot embossing, a pattern cylinder is pressed under high pressure and temperature against a preformed polymer web to create a homogenous product with a micro structured surface. In extrusion roll molding, a thin layer of molten polymer is pressed against a pattern cylinder to create a homogeneous product with a micro structured surface. The inherent appeal of a pattern cylinder, regardless of the process in which it is utilized, is its ability to enable manufacture of a product in a continuous manner. Continuous processes may provide lower manufacturing costs than batch processes.

Given the appeal of continuous manufacturing processes, one can efficiently create a cylinder containing the desired pattern of small cavities. Not only can one be able to create the exact desired pattern of small cavities, but also the time required to create the desired pattern over a large surface area must be reasonable. Surface areas to be patterned with small cavities typically range from 50 square inches to 3400 square inches, most ranging from 500 to 1500 square inches. It is desirable that the process required to create the pattern of small cavities could be accomplished in less than three days.

Many techniques are known in the art for creating pattern cylinders, but the list of techniques becomes shorter when the desired pattern has some optical utility. There are numerous uses for replicated patterns of small cavities that have optical utility. These applications include, but are not limited to, holograms used in security and packaging applications, micro lens arrays for telecommunications and imaging systems applications and light redirecting films used in backlit display systems. Examples of light redirecting films include diffusers, light collimating films and polarization recovery and recycling films.

Diamond tooling can be utilized to achieve the surface quality and roughness characteristics required for the creation of optical features. The precisely shaped and polished diamond tooling can be engaged with the cylindrical surface using any one of a variety of techniques, to either remove, shape or form the material on the cylindrical surface. While diamond tooling is expensive, it is preferred to more common and less expensive alternative tool materials. Alternative tool materials, such as carbide or high-speed steel, are not capable of producing optical quality features due to the relatively large grain size of the materials. This large grain size results in microchips along the cutting edges that will produce a surface with unacceptable roughness properties, thereby not meeting the requirements for a surface having optical utility. In order to produce optical quality features directly in a cylinder, the features can be cut, formed, scribed, ruled or otherwise created using a diamond tool or stylus.

Alternatives exist for indirectly creating a cylinder with the desired pattern of small cavities. For example one may create the desired pattern into a flat work piece, and through subsequent operations produce a flexible copy of the original that can be wrapped around a cylindrical surface. Utilizing such a technique will produce an easily detectable seam or line in the finished product, whose frequency is equal to the circumference of the cylinder. In some applications this may be acceptable, but in many applications it is not. This is particularly true when the finished product produced by replication or material transfer is of a length greater than the circumference of the cylinder.

It is well known that the time required to create a cylinder with the desired pattern of small cavities is a significant limitation of the various alternative methods for patterning such cylinders. In particular, the time required to create a cylinder with the desired pattern of small cavities can make the creation of such cylinders prohibitively expensive. All alternative processes have a capability to produce between one and ten features per second. At this rate, the time required to pattern an average cylinder used in a continuous manufacturing process would be measured in months. For example, if the desired pattern consists of 25,000 cavities per square inch and the surface area to be patterned is 1,500 square inches, at a rate of ten features per second, the time required to pattern a cylinder is 43 days. It is preferred to be able to create more than 100 cavities per second, and more preferred to be able to create more than 500 cavities per second.

Known techniques exist in the art for producing continuous optical grooves on a cylinder using diamond turning. In this process, a non-rotating diamond tool is engaged with a rotating cylinder. Typically a symmetric tool is engaged normal to the surface of the cylinder to produce a symmetric groove, consisting of two or more angled surfaces. While it is engaged with the cylinder it also may be moved further into the surface or retracted from the surface of the cylinder to produce variations in feature depth. If this is done in a continuous, non-linear motion, the resulting groove will consist of two or more curved surfaces. U.S. Pat. No. 6,581,286 (Campbell et al.) describes such a process for forming simple, continuous features by thread cutting. The grooves produced by this process are symmetrical, continuous and consist of two curved surfaces.

In other applications the diamond tool is moved parallel, perpendicular or at an angle to the rotational axis of the cylinder or work piece while engaged. A combination of any or all of these motions can occur simultaneously and the choice of motion selected is a function of the desired shape of the cavity being produced. Example applications of this method include the fabrication of the individual segments of a large mirror surface assembly.

Example embodiments of the present invention create a molding pattern for micro replication including a metal cylinder that is patterned with small, individual, three dimensional cavities by electro-mechanical engraving for the specific purpose of replicating the inverse of said three dimensional pattern into a continuous web of material.

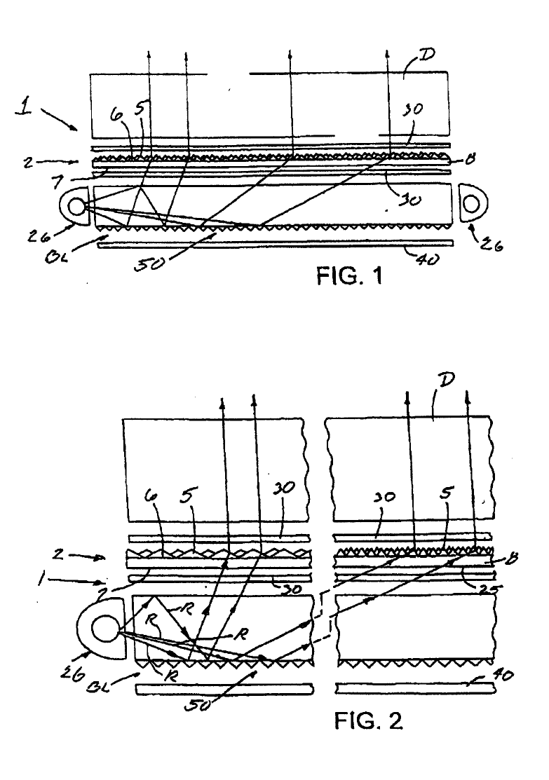

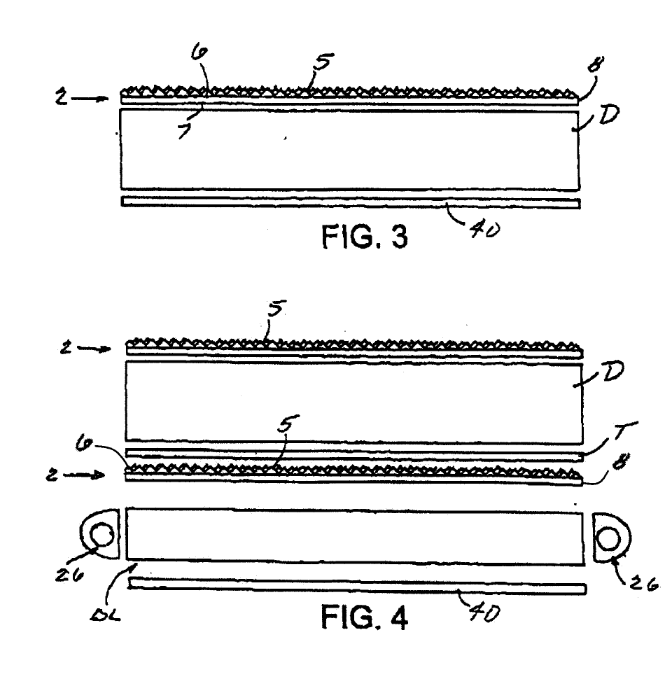

Example FIGS. 1 and 2 schematically show one form of light redirecting film system 1 in accordance with example embodiments of the present invention. Light redirecting film system 1 may include a light redirecting film 2 that redistributes more of the light emitted by a backlight BL (or other light source) toward a direction more normal to the surface of the film. Light redirecting film 2 may be used to redistribute light within a desired viewing angle from almost any light source for lighting. For example, light redirecting film 2 may be used with a display D (e.g. in a liquid crystal display, used in laptop computers, word processors, avionic displays, cell phones, and PDAs) to make the displays brighter. A liquid crystal display can be any type, including a transmissive liquid crystal display as schematically shown in example FIGS. 1 and 2, a reflective liquid crystal display as schematically shown in example FIG. 3, or a transflective liquid crystal display as schematically shown in example FIG. 4.

The reflective liquid crystal display D shown in example FIG. 3 may include a back reflector 40 adjacent the back side for reflecting ambient light entering the display back out of the display to increase the brightness of the display. The light redirecting film 2 in accordance with example embodiments of the present invention may be placed adjacent to the top of the reflective liquid crystal display to redirect ambient light (or light from a front light) into the display toward a direction more normal to the plane of the film for reflection back out by the back reflector within a desired viewing angle to increase the brightness of the display. Light redirecting film 2 may be attached to, laminated to or otherwise held in place against the top of the liquid crystal display.

The transflective liquid crystal display D shown in example FIG. 4 includes a transreflector T placed between the display and a backlight BL for reflecting ambient light entering the front of the display back out of the display to increase the brightness of the display in a lighted environment, and for transmitting light from the backlight through the transreflector and out of the display to illuminate the display in a dark environment. In example embodiments, the light redirecting film 2 may either be placed adjacent the top of the display or adjacent the bottom of the display or both as schematically shown in example FIG. 4 for redirecting or redistributing ambient light and/or light from the backlight more normal to the plane of the film to make the light ray output distribution more acceptable to travel through the display to increase the brightness of the display.

Light redirecting film 2 may include a thin transparent film or substrate 8 having a pattern of discrete individual optical elements 5 of well defined shape on the light exit surface 6 of the film for refracting the incident light distribution such that the distribution of the light exiting the film is in a direction more normal to the surface of the film.

Each of the individual optical elements 5 may have a width and length many times smaller than the width and length of the film, and may be formed by depressions in or projections on the exit surface of the film. These individual optical elements 5 may include at least one sloping surface for refracting the incident light toward the direction normal to the light exit surface. Optical elements 5 may have an aspect ratio greater than 0.5. Optical elements 5 may have a depth greater than 15 micrometers. These optical elements may take many different shapes. U.S. Patent Application Publication No. U.S. 2001/0053075 A1 titled “Light Redirecting Films and Film Systems” is hereby incorporated by reference in entirety. This application illustrates many variations of individual optical elements. However, one of ordinary skill in the art would appreciate other variations of optical elements of light redirecting systems that are covered by embodiments of the present invention.

As illustrated in example FIG. 2, light entrance surface 7 of the film 2 may have an optical coating 25 (e.g. an antireflective coating, a reflective polarizer, a retardation coating or a polarizer). Also, in example embodiments, a matte or diffuse texture may be provided on the light entrance surface 7 depending on the visual appearance desired. A matte finish may produce a softer image, that is not as bright. The combination of planar and curved surfaces of the individual optical elements 5 of example embodiments of the present invention may be configured to redirect some of the light rays impinging thereon in different directions to produce a softer image without the need for an additional diffuser or matte finish on the entrance surface of the film. The individual optical elements 5 of the light redirecting film 2 may also overlap each other in a staggered, interlocked and/or intersecting configuration, creating an optical structure with adequate surface area coverage.

The individual optical elements 5 may have multiple shapes and sizes on a light redirecting film 2. The individual optical elements 5 may also be placed on the surface in irregular patterns, where the spacing between neighboring elements varies. For example, random or pseudo-random placement of individual optical elements 5 on the light redirecting film 2 may be useful to avoid Moiré patterns or other optical effects when the light redirecting film is placed in an assembly with other optical components.

Irregular patterns comprise cavities that are placed in such a way that they do not follow a regular pattern such as a matrix, grid, or linear arrangement. Random patterns comprise cavities with locations chosen by a random process.

The backlight BL may be substantially flat or curved. The backlight BL may be a single layer or multi-layers and may have different thicknesses and shapes. The backlight BL may be flexible or rigid and be made of a variety of compounds. Further, the backlight may be hollow, filled with liquid, air, or be solid, and may have holes, ridges, or other optical deformities.

The light source 26 may be of any suitable type (e.g. an arc lamp, an incandescent bulb which may also be colored, filtered or painted, a lens end bulb, a line light, a halogen lamp, a light emitting diode (LED), a chip from a LED, a neon bulb, a cold cathode fluorescent lamp, a fiber optic light pipe transmitting from a remote source, a laser or laser diode, or any other suitable light source). Additionally, the light source 26 may be a multiple colored LED, or a combination of multiple colored radiation sources in order to provide a desired colored or white light output distribution. For example, a plurality of colored lights such as LEDs of different colors (e.g., red, blue, green) or a single LED with multiple color chips may be employed to create white light or any other colored light output distribution by varying the intensities of each individual colored light.

A back reflector 40 may be attached or positioned against one side of the backlight BL as schematically shown in example FIGS. 1 and 2 in order to improve light output efficiency of the backlight by reflecting the light emitted from that side back through the backlight for emission through the opposite side. Additionally, a pattern of optical deformities 50 may be provided on one or both sides of the backlight as schematically shown in FIGS. 1 and 2 in order to change the path of the light so that the internal critical angle is exceeded and a portion of the light is emitted from one or both sides of the backlight.

Thermoplastic films with textured surfaces have applications ranging from packaging to optical films. The texture may be produced in a casting nip that consists of a pressure roller and a pattern roller. Depending on the pattern being transferred to the thermoplastic film, it can be difficult to obtain a uniform degree of replication across the width of the film. It can also be difficult to obtain this uniform degree of replication and have a smooth backside to the film.

Preferred polymers for the formation of the surface structures include polyolefins, polyesters, polyamides, polycarbonates, cellulosic esters, polystyrene, polyvinyl resins, polysulfonamides, polyethers, polyimides, polyvinylidene fluoride, polyurethanes, polyphenylenesulfides, polytetrafluoroethylene, polyacetals, polysulfonates, polyester ionomers, and polyolefin ionomers. Copolymers and/or mixtures of these polymers to improve mechanical or optical properties can be used. Preferred polyamides for the optical elements include nylon 6, nylon 66, and mixtures thereof. Copolymers of polyamides are also suitable continuous phase polymers. An example of a useful polycarbonate is bisphenol-A polycarbonate. Cellulosic esters suitable for use as the continuous phase polymer of optical elements include cellulose nitrate, cellulose triacetate, cellulose diacetate, cellulose acetate propionate, cellulose acetate butyrate, and mixtures or copolymers thereof. Preferably, polyvinyl resins include polyvinyl chloride, poly(vinyl acetal), and mixtures thereof. Copolymers of vinyl resins can also be utilized. Preferred polyesters of the invention include those produced from aromatic, aliphatic or cycloaliphatic dicarboxylic acids of 4-20 carbon atoms and aliphatic or alicyclic glycols having from 2-24 carbon atoms. Examples of suitable dicarboxylic acids include terephthalic, isophthalic, phthalic, naphthalene dicarboxylic acid, succinic, glutaric, adipic, azelaic, sebacic, fumaric, maleic, itaconic, 1,4-cyclohexanedicarboxylic, sodiosulfoisophthalic and mixtures thereof. Examples of suitable glycols include ethylene glycol, propylene glycol, butanediol, pentanediol, hexanediol, 1,4-cyclohexanedimethanol, diethylene glycol, other polyethylene glycols and mixtures thereof.

A typical extrusion roll molding system comprises an extruder that extrudes molten polymeric material into a nip. The nip is formed between a pattern roller and a pressure roller. The molten polymer is forced into the pattern roller pattern by the pressure roller and cools. The polymer exits the nip in a semi-solid to solid state. Rubber pressure rollers may be used to provide a relatively uniform pressure across the casting nip, since their coverings can deform to accommodate any thickness non-uniformities in a melt curtain. These thickness non-uniformities may be due to the presence of thick edges from neck-in or from other causes of non-uniform flow from the extrusion die. However, the rubber coverings may not have a surface with low enough roughness to produce a glossy (e.g. smooth) backside surface.

In alternative embodiments, a pattern roller may be micro replicated into an optical film using other molding processes known in the art, including but not limited to UV casting, hot embossing, and solvent casting.

Example embodiments of the present invention relate to a method of electro-mechanical engraving a molding pattern in a rigid surface. The molding pattern may be for micro-replicating optical elements during manufacturing of light redirecting films. The electro-mechanical engraving may be Gravure electro-mechanical engraving. Gravure electro-mechanical engraving processes have been used to produce printing rollers in the printing industry. However, example embodiments of the present application use electro-mechanical engraving for the entirely different purpose of making a molding pattern.

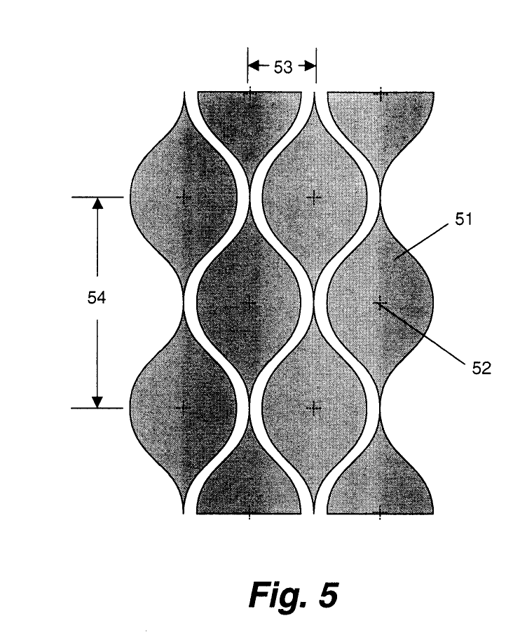

In typical electromechanical engraving, the cavities cut on a cylinder are placed in a regular pattern. FIG. 5 is an illustration of a portion of a typical image cut by an electromechanical engraving machine, showing cavities 51 with center points 52 placed in a regular offset grid with constant spacing 53 and 54 between cavity centers. The vertical direction is aligned around the cylinder, and the horizontal or X direction is aligned with the axis of the cylinder. The spacings 53 and 54 together define the screen and angle of the electromechanically engraved image, and they are constant across the image. The image is engraved by engraving a column of cavities in a single revolution of the cylinder, then moving the engraving head along the axis of the cylinder by the constant distance 53, then engraving the next column of cavities, and repeating.

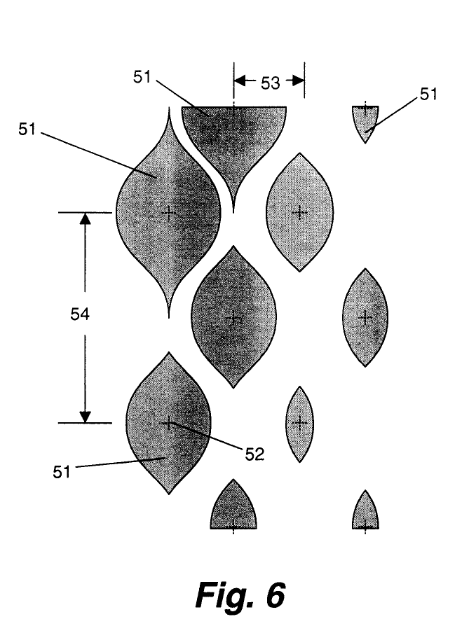

FIG. 6 is an illustration of another portion of a typical image cut by a Gravure electromechanical engraving machine. The cavities 51 are cut at varying depths into the surface of the cylinder, causing variations in cavity size and shape. The cavity depth variations are provided to transfer varying amounts of material, for example ink or a coating material, at that point in the image. However, the cavity locations are still arranged in columns with fixed spacing 53. The electromechanical engraver always moves a constant distance from one column to the next. Repeating patterns of optical elements, such as those that would be produced by a typical electromechanical engraving process with constant offset between columns of cavities, can have detrimental optical effects such as Moiré when the product is placed in an assembly with other optical components.

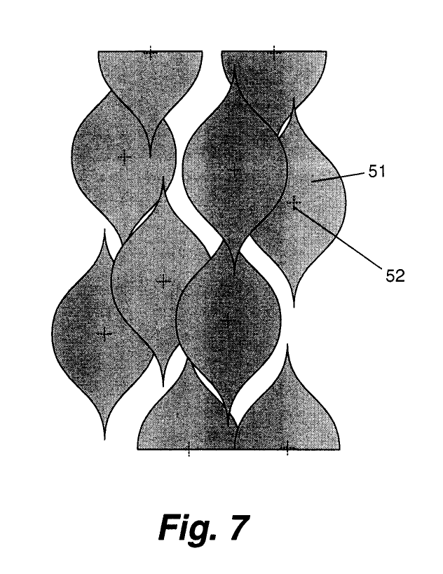

Example embodiments of the present invention significantly modify the electromechanical engraving process to provide irregular positioning of cavities for replicating three-dimensional micro-features. The electromechanical engraver may be modified to allow varying offset between columns of cavities, to allow arbitrary, irregular, or random cavity positions. The arbitrary, irregular, or random cavity positions may also cause the cavities to intersect and interlock in arbitrary, irregular, or random ways. FIG. 7 is an illustration of an irregular or pseudo-random pattern of intersecting cavities that might be cut according to one embodiment of the present invention. FIG. 7 shows cavities 51 with gaps between them for simplicity of illustration. The cavity positions may also be irregular or random yet substantially cover the surface of the cylinder. The arbitrary, irregular, or random cavity positions and intersections can have beneficial effects for the product molded from the cylinder, including reduction of Moiré effects in optical substrates.

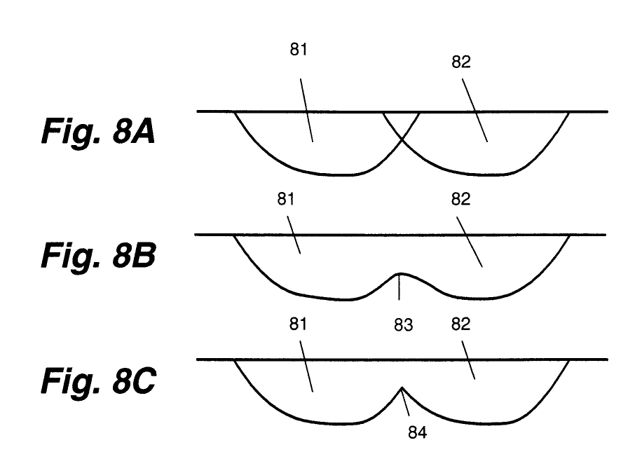

The varying offset between columns of cavities can also be allowed to be zero, thereby causing the electromechanical engraver to engrave multiple columns of cavities in the same X location. This capability can be useful in several ways for making tools for micro replication. The edges of neighboring cavities that are engraved sequentially by an electromechanical engraver cannot have sharp edges between them, due to momentum of the engraving head and stylus. FIG. 8A is an illustration of a side view of two neighboring overlapping cavities 81 and 82. In FIG. 8B, if the cavities are engraved in succession by an electromechanical engraver, they will have a rounded intersection point 83. However, as illustrated in FIG. 8C, by engraving neighboring features 81 and 82 in two columns cut at the same location, a sharp transition 84 can be achieved between the two cavities.

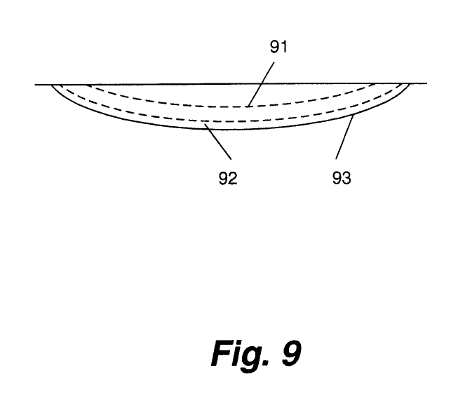

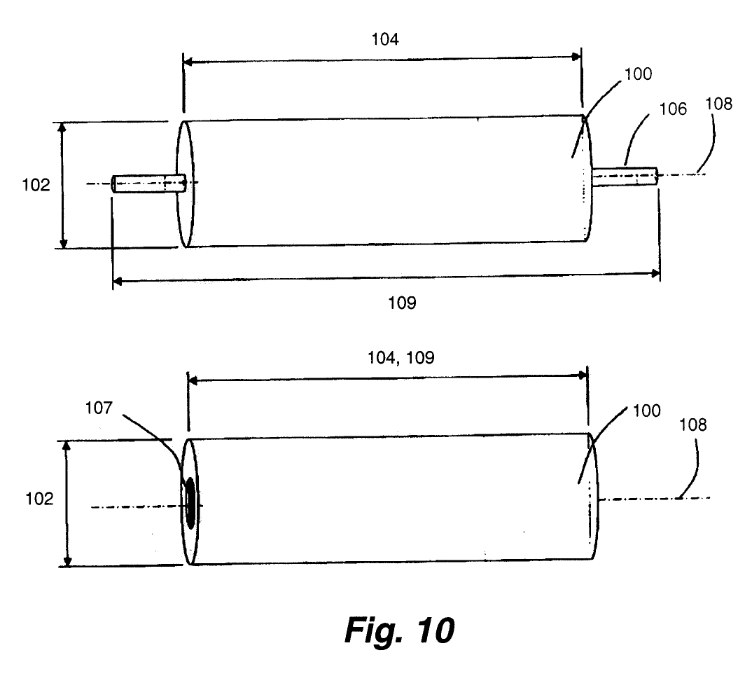

Tools for micro replication may need to have cavities that are deeper than can be cut in a single cut, or they may need to be made out of harder materials than are typically electromechanically engraved, such as nickel or nickel-phosphorous alloys. Engraving deep features in these harder materials might stress the diamond stylus to fracture, or optical-quality surfaces may no longer be achieved. Engraving multiple columns of cavities in the same X location can address these issues by cutting a cavity to increasing depths in each column. For example, as illustrated in FIG. 9, the first column of engraving might cut (91) the cavity to 50% of its final depth, the second column of engraving at the same location might cut (92) the cavity to 90% of its final depth, and the third and final column of engraving at the same location might cut (93) the cavity to its final depth. As a result the feature can be cut to arbitrary depths, the stylus is subjected to lower cutting forces, and the surface finish of the cavity can be of optical quality.

FIG. 10 is an illustration of a cylinder 100, into which the desired pattern of cavities may be generated, in accordance with example embodiments of the present invention. The configuration of the cylinder can vary significantly, and is often customized for the specific end use. In all configurations the cylinder has a nominal diameter 102, associated with a nominal face length 104. The cylinder may either have shafts 106 or a tapered mounting hole 107, on the ends of the nominal diameter that define the axis of rotation 108. The overall length of the cylinder 109, may be equal to the face length if the cylinder does not have shafts. More typically the cylinder does have shafts, whose length would be included in the overall length of the cylinder.

The cylinder may be hollow or solid, but in either case the cylindrical surface will have some associated thickness of the specific material required to achieve the desired results. In particular, if the desired pattern of cavities is to have optical utility, the cylindrical surface may be a non-ferrous material or alloy, so that it may be machined successfully using a diamond tool. In addition the material preferably has a very small grain structure or is amorphous, and is free of inclusions, pits, voids and other defects that will affect the optical utility of the desired pattern. Examples of such materials include, but are not limited to: copper and copper-nickel alloys, nickel and nickel-phosphorus alloys and high purity aluminums.

The cylindrical surface into which the machining will occur can either be wrought or plated. In wrought form the material may comprise the entire cylindrical surface or it may be pressed or otherwise sleeved over an existing cylindrical surface made from a less expensive material. In plating, an electro-chemical process or alike is used to transfer the desired material uniformly and in a thin layer onto the outside of the cylinder surface. This plating process can also be done over a mandrel to create a thin sleeve of the preferred material. This sleeve can then be patterned with the desired cavities or grooves and then transferred to the preferred cylinder for use in replication or material transfer. This sleeve can also be removed from the mandrel and transferred to the preferred cylinder prior to forming of the desired cavities.

After forming of the desired pattern of cavities, the sleeve can be removed and used as a belt in a replication or material transfer process. The sleeve can also be cut to size and used in the flat state for a replication process such as injection molding or thermoforming.

In another embodiment, the roller may comprise a polymer surface. Polymer surfaces may be diamond turned or electro-mechanically engraved and have high replication fidelity. Polymer rollers are useful as a replication master for electro-plating processes and also can be used for casting of aqueous and solvent dispersions of polymers. Suitable polymers include PTFE, Delrin, and Capton.

Electromechanical engravers and diamond turning machines with fast tool servos are both examples of cutting machines for cylinders, but they have significant differences. Diamond turning machines must be built to extremely fine tolerances to achieve high positioning accuracy in the direction of the cylinder's axis as well as radially (normal to the surface of the cylinder). Furthermore, if the fast tool servo attachment moves large distances at high frequency, it may induce vibrations in the radial direction, reducing depth accuracy. Achieving high accuracy in depth also requires either finishing the roller surface on the same diamond turning machine before cutting cavities, or providing a very precise roller surface and mounting the roller with extremely low runout. An example diamond turning machine with fast-tool servo capability is the Vertical Drum Lathe available from Moore Tool Company of Bridgeport, Conn.

Electromechanical engravers are made with mature technology that addresses some of these issues in a cost-effective and reliable way. A diamond stylus is mounted on an arm attached to a rod in an engraving head that also has a shoe mounted in it. Typically the stylus has a simple cross section consisting of two straight cutting edges that meet each other in an apex; sometimes the apex is chamfered. A force is applied to the engraving head, causing the shoe to rest against the roller surface. As the cylinder turns, twisting motions are induced in the rod by electromagnets, causing the stylus to move in and out of the cylinder surface. The motion of the stylus is synchronized with the rotational position of the cylinder using an encoder attached to the rotational axis. Electromechanical engravers are designed to achieve high speed, for example up to 8,000 Hz, for fast production of rollers for printing and material-transfer applications. They are also capable of large cutting depths, for example up to 100 micrometers or more. The HelioKlischograph K500 available from Hell Gravure Systems of Kiel, Germany is an example electromechanical engraver. Electromechanical engravers can also be configured to engrave on flat surfaces using similar methods, either rotating the workpiece or by a relative translational motion. A short description is provided here, but is not meant to limit the definition of electromechanical engraving. Those skilled in the art will know additional variations not described. U.S. Pat. No. 6,515,772, incorporated here by reference, describes control and setup methods for an electromechanical engraving system.

With modifications described herein, electromechanical engraving machines have several distinct advantages for patterning micro-scale cavities on rollers or molds for optical applications. The shoe resting against the cylinder surface provides a radial positional reference to the surface, allowing highly repeatable depth positioning relative to the cylinder surface. This can save considerable time and expense on the machine to finish the roller or fixture it accurately. Furthermore, the engraver can be made to lower tolerances as well, because it need not provide accurate positioning in the radial direction. In yet another advantage, the shoe riding on the surface provides a damping function against vibration or inaccuracy due to fast and/or large motions of the cutting head and diamond stylus.

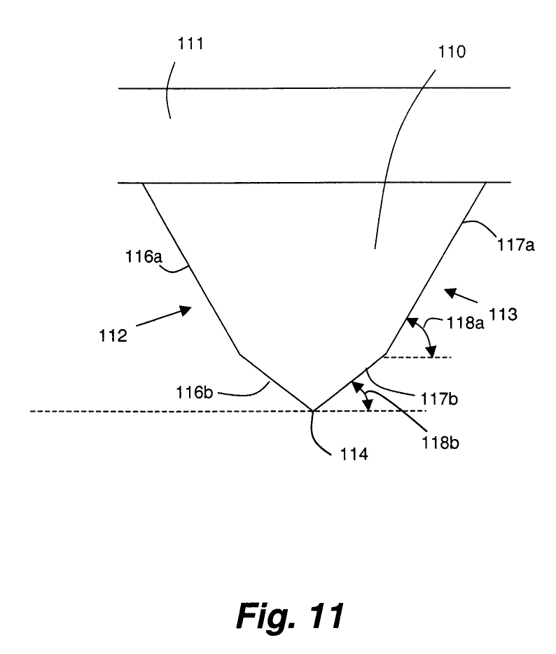

In embodiments, the present invention may be used to fabricate light extracting features as described in U.S. patent application Ser. No. 11/388,582, incorporated herein by reference. In this application, individual cavities of finite length and width are cut into a roller, and the roller is used to mold a light extracting film having light extracting features that are substantially the negative shape of the cavities on the roller. A cross section of an example light extracting feature 110 is shown in FIG. 11. The light extracting feature may be formed on a substrate 111, or the features 110 and substrate 111 may be integral and made of the same material. The light extracting features 110 have a complex cross section consisting of two sides 112 and 113 that meet at an apex 114. Side 112 consists of two or more linear segments 116a, 116b and side 113 consists of two or more linear segments 117a, 117b. Line segments 117a and 117b have corresponding angles 118a, 118b to the horizontal direction. The light enters light extracting features 110 in a known and well-defined input distribution, and exits in a desired and well-defined output distribution. The complex cross section of the cavities and light extracting features 110 are critical to the correct fabrication and operation of the light extracting film. In an example embodiment, there are approximately 70 light extracting features per square millimeter of the roller surface, and a cylinder pattern of approximately 0.15 square meters consists of over 10 million cavities.

As used herein, the cross section of a cavity is its cross section in the plane perpendicular to its longest dimension. A complex cross section of a cavity is a cross section that consists of more than three line segments or that contains curves that are parabolic, elliptical, circular arcs, or other well-defined curved shapes such as those defined by an aspheric equation. A complex cross section stands in contrast to the simple cross section of a diamond stylus typically used with electromechanical engraving machines, which has two line segment cutting edges that meet at an apex, where the apex may have an optional flat tip. Because the shape of the cavity in the mold is substantially the negative of the shape of the diamond cutter that cuts it, and the shape of the cavity in the mold is substantially the negative of the shape of the optical element formed from it, we will speak of complex cross sections as applying equally to cavities, optical elements, and diamond cutters.

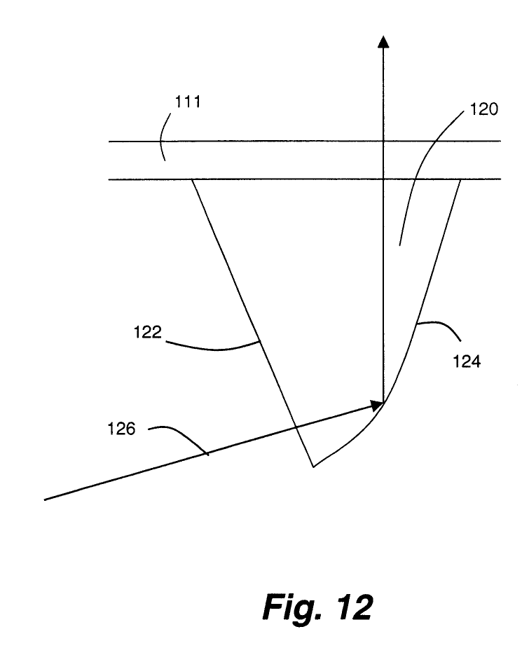

Another example of a complex cross section is shown in FIG. 12. Light turning feature 120 is formed on substrate 111 as part of a turning film. Light turning feature 120 has a complex cross section with a first side 122 that is a straight line segment and a second side 124 that is curved. Light rays 126 enter light turning feature 120 through first side 122 in a known and well-defined input light distribution, are totally internally reflected at second side 124, and exit the turning film in a well-defined desired output distribution that is brightest approximately normal to the substrate 111. The curved shape of second side 124 optimizes the on-axis brightness of the resulting output light distribution. For this reason, the complex cross section of the light turning feature 120, and the corresponding complex cross section of the mold cavity, are critical to the correct operation of the turning film.

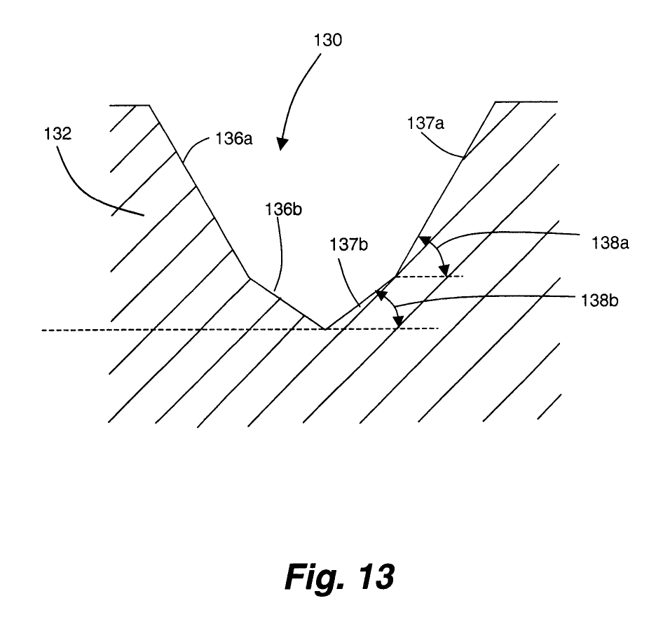

FIG. 13 shows a cross section of an example cavity 130 that might be cut into a mold 132 to mold the light extracting feature 110 of FIG. 11. The cross section of cavity 130 has a first side consisting of multiple line segments 136a, 136b and a second side consisting of line segments 137a,137b. Line segments 137a, 137b have angles 138a, 138b with the horizontal direction, respectively.

In some cases the molding process may cause light extracting features 110 to have a somewhat different shape than the negative of cavities 130. For example, a UV-cured polymer may shrink anisotropically when it cures, perhaps because some dimensions are constrained by the substrate 111. This may cause angles 118a, 118b to be different than angles 138a, 138b, and it may cause the length of segments 116b, 117b to be longer or shorter than the lengths of segments 136b, 137b. Other cases of predictable shape changing during molding will be known to those skilled in the art. In such cases, the cavity 130 cross section may be fabricated in a modified way to correct for such molding distortions. For example, if light extracting feature angle 118a is consistently 1 degree smaller than cavity cross section angle 138a, then angle 138a may be cut 1 degree larger to achieve the desired angle 118a.

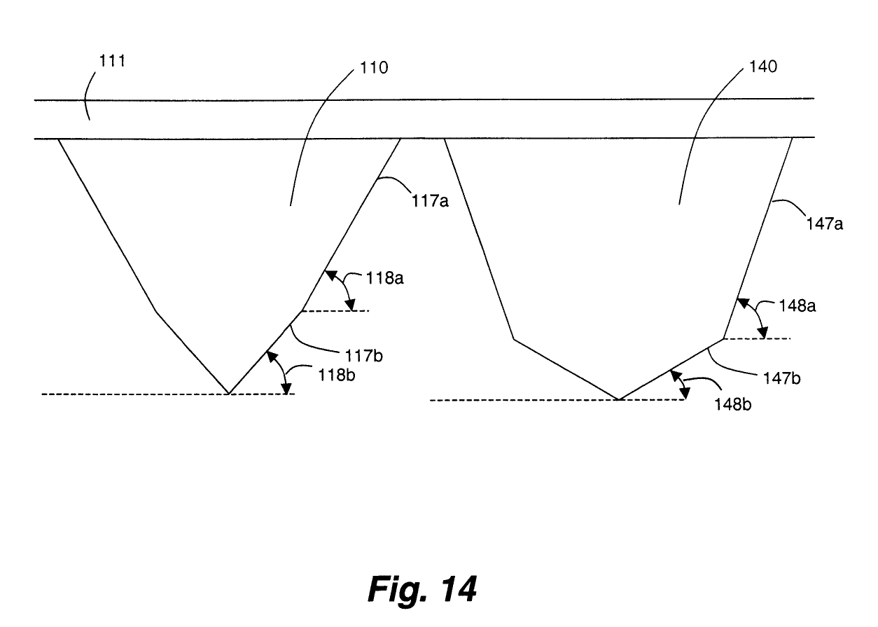

In yet another embodiment of the present invention, multiple cavity cross sections may be cut on a single surface. FIG. 14 shows a cross section of an example light extracting film that has light extracting features 110, 140 with two cross sectional shapes. Feature 110 has line segments 117a, 117b that have lengths and angles 118a, 118b. Feature 140 has line segments 147a, 147b that have lengths as well as angles 148a, 148b that are different than the corresponding lengths and angles 118a, 118b of feature 110. A light extracting film could have additional light extracting feature cross sectional shapes, or asymmetric cross sectional shapes. The different feature cross sections will shape the extracted light in different ways. In a portion of the light guide plate near one light source, the light will have a certain directional distribution that might be extracted in the best way by light extracting feature 110. In a portion near the center of the light guide plate, the light will have a different directional distribution that might be extracted in the best way by light extracting feature 140. Furthermore, in any region of the light guide plate, the optimal light output distribution might be obtained by a mix of light extracting features of multiple shapes. As a result, the optimal light extracting film may be composed of light extracting features with multiple cross sections, interspersed on the film in varying densities and arrangements.

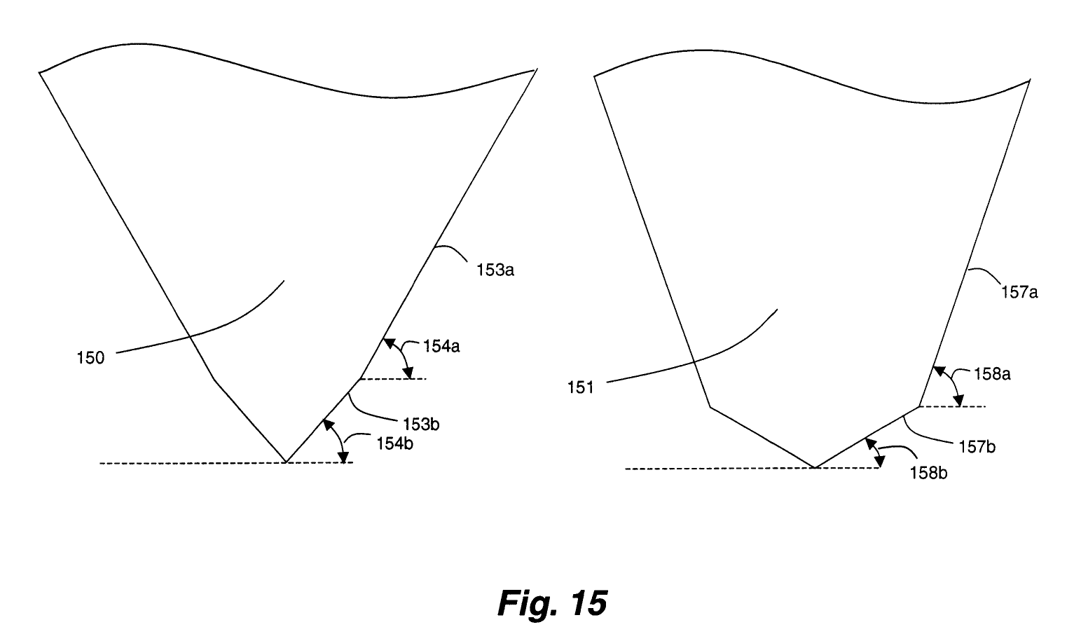

A mold for a light extracting film with multiple light extracting feature cross sections may be produced by cutting cavities with multiple cavity cross sections, using a diamond cutter for each cross section. FIG. 15 shows front views of two diamond cutters 150, 151 that might be used to cut cavities 110, 140 respectively. Cutter 150 has cutting edges 153a, 153b where the length of edge 153b is substantially equal to the length of cavity cross section segment 117b, and angles 154a, 154b are substantially equal to angles 118a, 118b respectively. Similarly, cutter 151 has cutting edges 157a, 157b where the length of edge 157b is substantially equal to the length of cavity cross section segment 147b, and angles 158a, 158b are substantially equal to angles 148a, 148b respectively. By cutting one set of cavities using cutter 150, and another set using cutter 151, multiple cavity cross sections may be cut on a single surface, interspersed as needed. Other cavity cross sections may be cut by additional diamond cutters as needed.

In one embodiment, a first set of cavities is cut using cutter 150, and then cutter 151 is loaded into the electromechanical engraving head, and the second set of cavities is cut. The two sets of cavities are independently determined, so that there need not be a one-to-one correspondence between cavities in the first set and cavities in the second. Independently determined sets of cavities may have different placements, cavity lengths and cross sectional shapes, densities across the pattern, and other differences that will be known to those skilled in the art. In addition, the cavities cut by a single diamond cutter may vary in depth, length, and other attributes.

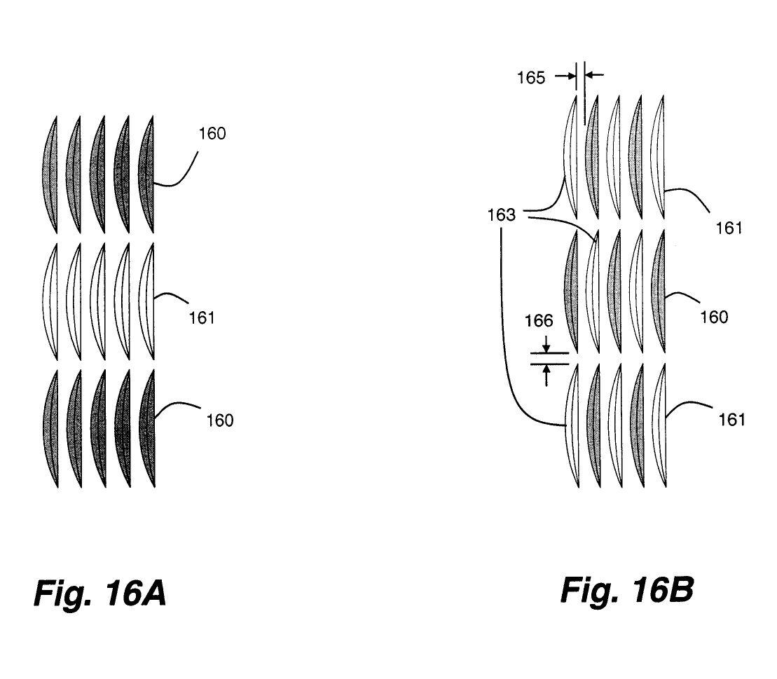

The two sets of cavities may be accurately positioned relative to each other by the following method. In a test region of the cylinder, preferably near one edge, cavities are cut by both cutters in an interspersed pattern, placing cavities of the first set between cavities of the second set, and vice versa. FIG. 16A and FIG. 16B show top views of two possible patterns of interspersed cavities that may be used for accurately positioning cavities cut by two cutters. The interspersed sets of cavities designed for relative positioning are called registration patterns. With the benefit of the present disclosure, other suitable arrangements will be known to those skilled in the art. Cavities 160 in the first set (shown shaded) are cut first, along with the rest of the cavities in the first set across the cylinder. Then second cutter 151 is loaded into the engraving head, and a small portion of the cavities 161 in the second set (shown white) are cut. For example, the engraver might be commanded to cut two columns of cavities 163. Then the engraver is stopped and a microscope may be used to examine the relative position of cavities 160, 163. For example, the distance 165 between sides of cavities 160, 163 may be measured, and the distance 166 between ends of cavities 160, 163 may be measured. Measuring and adjusting the relative positions of cavities bypasses and compensates for errors in cutter geometry, cutter placement in the cutting head, and cutting head placement that otherwise would affect positioning accuracy. Positions of multiple cavity pairs may be measured and averaged to achieve higher accuracy in practice. The measured relative position between the cavities 160, 161 is compared to the intended position, and the position of the cavities 161 may then be adjusted. Position of cavities 161 may be adjusted by physical adjustments such as adjusting mounting screws on the engraving head. Preferably position of cavities 161 is adjusted by commands to the control software of the electromechanical engraving machine to shift the position in axial and circumferential directions. After adjusting the position of cavities 161, another portion of cavities 161 may be cut, measured, and adjusted, until a highly accurate relative position is obtained. Once the two sets of cavities are in correct relative position, the engraver may be commanded to complete engraving the second set of cavities with cutter 151.

In experiments, relative positioning accuracies of less than 5 micrometers may be obtained consistently with the above method, and relative positioning accuracies of approximately 1 micrometer may be obtained by measuring and averaging relative positions of multiple cavity pairs. Some additional relative error between the first and second sets of cavities is induced by inaccuracies in the positioning of the electromechanical engraver, temperature-induced positioning changes, and other sources known to those skilled in the art. The first and second sets of cavities may be kept in relative position to accuracies of less than 20 micrometers with relative ease. Accuracies of 10 micrometers and 5 micrometers have been obtained by application of additional methods known to those skilled in the art, such as careful attention to temperature control, accurate electromechanical engraver positioning components, and averaging relative positions measured on multiple cavity pairs as described herein.

In an alternative embodiment, multiple engraving heads are mounted on a single engraving machine, for example on opposite sides of the cylinder, and the two sets of cavities are cut simultaneously. In this case, a first portion of the interspersed cavities 160, 161 in the registration pattern may be cut in a test region of the cylinder by both cutters 150, 151. Then the first portion of the cavities 160, 161 may be measured, the relative position of the two cutters is adjusted as above, and then the process is repeated. When the relative position of the first set and second set of cavities is measured to be in correct position, the engraving machine may be allowed to cut the rest of the two sets of cavities simultaneously. This embodiment may achieve higher overall cutting speed at the cost of a second engraving head and machine and control complexity.

When more than two cutters are to be used, the first cutter may cut a first set of cavities to be used as a reference, including one or more registration patterns. Each successive cutter places additional cavities interspersed with the first set of cavities in registration patterns, and the position of the additional cavities relative to the first set of cavities is measured and adjusted as described above. If desired, cavities cut by the third cutter may be measured relative to cavities cut by both the first and second cutters, or they may be measured against only one of the previous sets of cavities.

In another embodiment, multiple cutters may be used to cut sets of cavities that have the same cross section. This may be of use when cutter wear is an issue. For example, in some cases a pattern roller must be fabricated of a hard substance such as a nickel-phosphorous alloy to withstand stresses or wear induced by the molding process. In this case, diamond cutters may wear too much to allow cutting an entire pattern of cavities on the roller using a single diamond cutter. As the cutter wears, cut finish quality may degrade, visual artifacts may emerge, or the cross sectional shape of the cavities may change. Multiple cutters may be used to cut the cavities on the roller to achieve the pattern size desired while keeping wear on each cutter within required bounds. To avoid visible lines in the pattern due to slightly different cutting from the multiple cutters, it is preferred to intersperse cavities from the multiple cutters across the cylinder.

In another embodiment, a first cutter may cut a registration pattern after it has cut a first set of cavities in the cylinder while traveling in a first axial direction. The cavities cut by a second cutter may be registered into correct relative position in the registration pattern, after which the second cutter cuts a second set of cavities while traversing the cylinder in the opposite axial direction from the first cutter. This method may distribute cutter wear more evenly across the cylinder, because the first cutter is worn at the end of its cut where the second cutter has experienced little wear, and vice versa. However, this method may induce additional inaccuracies in machine positioning due to the different axial movement directions.

In another embodiment, a single cutter may be kept mounted in the engraver and used to cut multiple sets of cavities that are described above as being cut by different cutters with the same shape. This embodiment will not reduce overall wear on the cutter, but it will spread the wear across the cavities in a more even distribution. For example, if a cutter cuts a single set of cavities across the cylinder, then the cutter will be sharp at one end of the cylinder and have wear at the other end. If instead the single set of cavities is divided into 2 or more interspersed sets of cavities cut in succession by a single cutter, then the wear on the cutter, and any corresponding changes in surface finish or shape, will be more evenly distributed across the cylinder.

In preferred embodiments, the cylinder is kept mounted on the electromechanical engraving machine from before the first set of cavities is cut until after the last set of cavities is cut. If the cylinder is removed from the engraver, then any inaccuracies in remounting it to the same position will be reflected in additional inaccuracy in relative positioning of any subsequent cavities that are cut. In some cases it is advantageous to remove the cylinder, rotate it 180 degrees to swap its ends in the engraver, and then cut additional cavities that may have an alternate orientation.

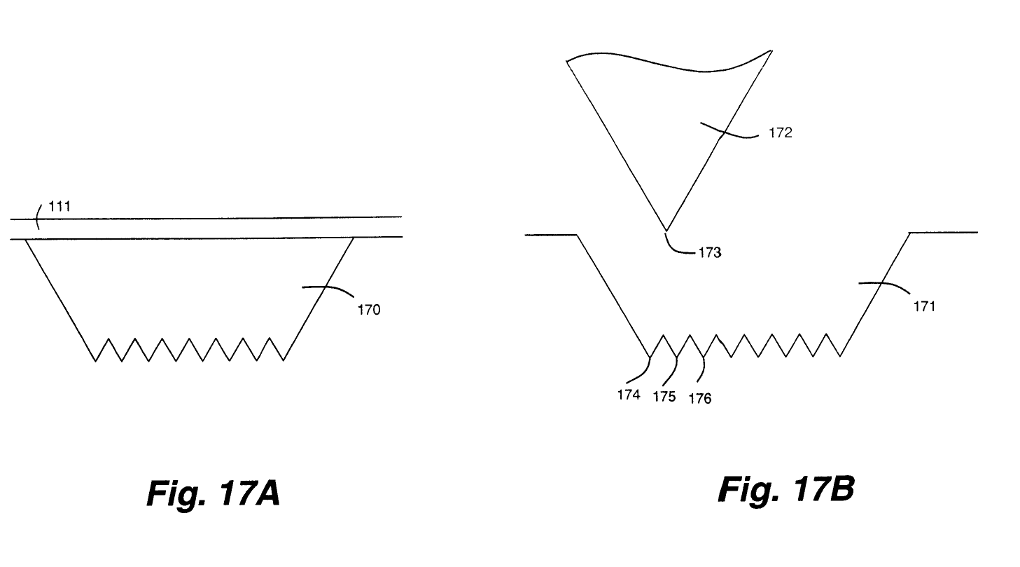

In another embodiment, cavities with complex cross sections may be formed by multiple overlapping cuts of a cutter. FIG. 17A shows an example cross section of a feature 170 on an optical film substrate 111 molded from such a cavity. FIG. 17B shows a cross section of the corresponding cavity 171 and a cutter 172 with a simple cross section that could be used to cut cavity 171. A cutter with a complex cross section could also be used to achieve complex cavity cross sectional shapes with overlapping cuts. Cutter 172 may cut overlapping cuts with its apex 173 placed in horizontal positions corresponding to points 174, 175, 176 to achieve in combination the overall shape of cavity 171.

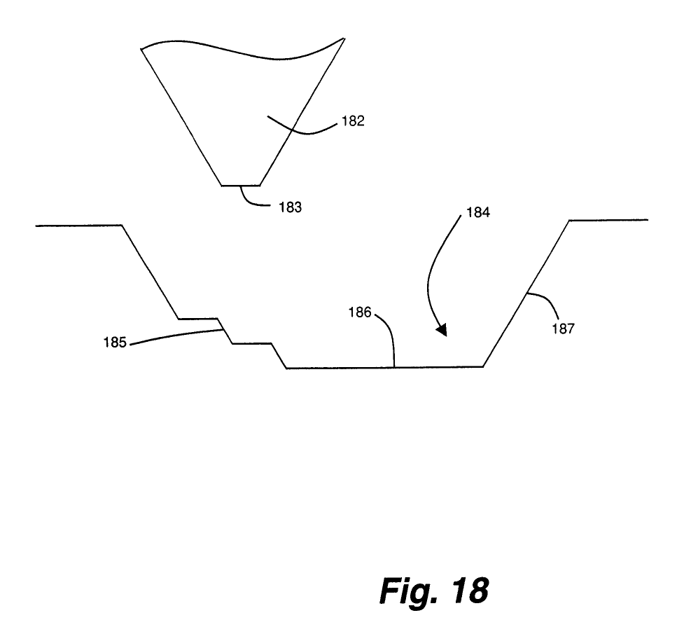

FIG. 18 shows yet another possible embodiment. A cutter 182 with a flat tip 183 may be used in overlapping cuts of different depths to cut a cavity 184. Cavity 184 has a complex cross section with a stepped side 185, a flat bottom 186 that is wider than the flat 183 on cutter 182, and a straight side 187.

The invention has been described in detail with particular reference to certain preferred embodiments thereof, but it will be understood that variations and modifications can be effected within the spirit and scope of the invention.

### PARTS LIST

1; Light redirecting film system
2; Light redirecting film
5; Optical elements
6; Light exit surface
7; Light entrance surface
25; Optical coating
26; Light source
30; Optical diffuser layers
40; Back reflector
51; Cavity
52; Center point
53; Horizontal spacing
54; Vertical spacing
81, 82; Cavity
83; Rounded intersection point
84; Sharp transition
91, 92, 93; Cut
100; Cylinder
102; Diameter
104; Length
106; Shaft
107; Hole
108; Axis of rotation
109; Length of cylinder
110; Light extracting feature
111; Substrate
112, 113; Side
114; Apex
116a, 116b 117a, 117b; Linear segment
120; Light turning feature
122; First side
124; Second side
126; Light ray
130; Cavity
132; Mold
136a, 136b, 137a, 137b; Line segment
138a, 138b; Angle
140; Light extracting feature
147a, 147b; Line segment
148a, 148b; Angle
150, 151; Diamond cutter
153a, 153b, 157a, 157b; Cutting edge
154a, 154b, 158a, 158b; Angle
160, 161, 163; Cavity
165, 166; Distance
170; Feature
171; Cavity
172; Cutter
173; Apex
174, 175, 176; Point
182; Cutter
183; Flat tip
184; Cavity
185; Stepped side
186; Bottom
187; Straight side
BL; Backlight
D; Display
R; Rays

1. A method comprising
electro-mechanical engraving cavities with a complex cross section into the surface of a mold, followed by
micro replicating an article comprising protrusions having well defined shapes that are substantially the negative of the cavity shapes.

2. The method of claim 1, wherein the electro-mechanical engraving comprises:
moving the surface at a constant velocity; and
moving a diamond stylus in and out of the surface by applying an alternating voltage to a series of magnets to create a twisting motion in a rod, wherein the diamond stylus is attached to the rod to create the cavities.

3. The method of claim 1, wherein the electro-mechanical engraving comprises:
mounting a shoe and diamond stylus in a cutting head;
moving the surface at a constant velocity;
placing the shoe against the surface to register the cutting head position relative to the surface; and
moving the diamond stylus in and out of the surface to create the cavities.

4. The method of claim 1, wherein the surface is a cylinder.

5. The method of claim 4, wherein the mold is a pattern roller and micro replicating is performed in a continuous process.

6. The method of claim 1, wherein the micro replicating is molding.

7. The method of claim 1, wherein the article is a light redirecting film.

8. The method of claim 1, wherein the article is a light extracting film.

9. The method of claim 1, wherein the complex cross section comprises circular, parabolic, elliptic, or aspheric curves.

10. The method of claim 1, wherein the complex cross section comprises four or more line segments.

11. The method of claim 1, wherein the protrusions are individual optical elements having lengths and widths that are both small relative to the corresponding dimensions of the article.

12. The method of claim 1, wherein the complex cross section is formed by multiple overlapping cuts.

13. The method of claim 1, wherein the cross section of the cavities compensates for distortion induced by the micro replicating process, such that the protrusions have a desired well-defined shape.

14. The method of claim 1, wherein the article is a first article, and further comprising micro replicating the first article to produce a second article having cavities that are substantially the positive shape of the surface cavities.

15. A method of cutting cavities into a surface, comprising
mounting a mold onto a cutting machine, the mold having a surface,
cutting a first set of cavities into the surface with a first diamond cutter according to a first pattern at a rate of more than 10 cavities per second, and
cutting a second set of cavities into the surface with a second diamond cutter according to a second pattern at a rate of more than 10 cavities per second,
wherein the first pattern and second pattern are independently determined, and wherein the positions of cavities in the first set are in defined relative position to the cavities in the second set, the defined relative position being accurate to a tolerance that is less than 20 micrometers.

16. The method of claim 15, wherein the defined relative position is accurate to a tolerance that is less than 10 micrometers.

17. The method of claim 15, wherein the first diamond cutter and the second diamond cutter have substantially the same cross section.

18. The method of claim 15, wherein the first diamond cutter and the second diamond cutter have substantially different cross sections.

19. The method of claim 15, wherein at least one of the first diamond cutter and the second diamond cutter has a complex cross section.

20. The method of claim 15, wherein the surface is a cylinder.

21. The method of claim 15, further comprising micro replicating an article comprising protrusions having well defined shapes that are substantially the negative of the cavity shapes.

22. The method of claim 21, wherein the mold is a pattern roller and wherein the micro replicating is performed in a continuous process.

23. The method of claim 21, wherein the protrusions are individual optical elements having lengths and widths that are both small relative to the corresponding dimensions of the article.

24. The method of claim 15, wherein the cutting is electro mechanical engraving.

25. The method of claim 15, wherein the cutting is performed by a diamond turning machine with a fast tool servo.

26. The method of claim 15, wherein the first set of cavities is cut and then the second set of cavities is cut.

27. The method of claim 15, wherein the mold is not removed from the cutting machine between cutting the first set of cavities and the second set of cavities.

28. The method of claim 15, wherein at least one of the first set of cavities and the second set of cavities is cut at a rate of greater than 100 cavities per second.

29. The method of claim 15, wherein at least a portion of the first set of cavities is interspersed with at least a portion of the second set of cavities.

30. The method of claim 15, further comprising the steps of
a) cutting a portion of the second set of cavities,
b) measuring the position of the portion of the second set of cavities relative to a portion of the first set of cavities, and
c) adjusting the position of the second set of cavities,
performing steps a, b, and c one or more times until the portion of the first set of cavities is in the defined relative position to the second set of cavities accurate to less than the tolerance, and then cutting the remainder of the second set of cavities.
